(19) United States
(12) Patent Application Publication
(10) Pub. No.: US 2025/0160223 A1
(43) Pub. Date: May 15, 2025

(54) Helium-4 Integrated Graphene Layer Encased Within A Mercury Telluride Bilayer

(71) Applicant: DeMarcus Oshay Carney, Winston Salem, NC (US)

(72) Inventor: DeMarcus Oshay Carney, Winston Salem, NC (US)

(21) Appl. No.: 18/831,195

(22) Filed: Sep. 6, 2024

Related U.S. Application Data
(63) Continuation-in-part of application No. 18/171,610, filed on Mar. 6, 2023, now abandoned.

(51) Int. Cl. H10N 70/20; B82Y 10/00; G06N 10/40; H10N 70/00

(52) U.S. Cl. CPC H10N 70/25; B82Y 10/00; G06N 10/40; H10N 70/8828; H10N 70/8845; H10N 70/023

(57) ABSTRACT

The primary structure of my invention is comprised of only three components: mercury telluride (1), graphene (2), and superfluid helium-4 (3). When these three components are assembled in a parallel arrangement so that they form a tri-layer consisting of two separate identical layers of mercury telluride (1) that bilaterally encase a central layer of graphene (2), in which the central graphene (2) layer is integrated with superfluid helium-4 (3), then this said structure manifests a favorable environment for enabling electrical signals. The entire exterior surface of this tri-layer structure is lastly encased within a uniform layer of gold (4) and this external layer of gold (4) assists in protecting the integrity of both the mercury telluride (1) layers, as well as amplifies the completed tri-layer structure's ability to conduct electrical signals. This tri-layer laminate structure also includes one or more hermetic seals (5) and microfluidic channels (6).

### CROSS-REFERENCE TO RELATED APPLICATIONS

This application is a continuation in-part of U.S. application Ser. No. 18/171,610, filed on Mar. 6, 2023, which is hereby incorporated by reference.

### BACKGROUND OF THE INVENTION

The technical field associated with my proposed invention lies within the realm of physics. The foremost fitting embodiment of my invention favors its intended fabrication as an ion trap that is equipping and employed by an ion trap quantum computer, conformant with the quantum computing industry. Quantum computers have exponentially gained relevancy within today's society, due to their exceptional potential to solve complex problems exceptionally faster than regular computers. There are a few distinct types of quantum computers in which each of these different systems use qubits to process information. Ion trap quantum computers are specifically designed incorporating an ion trap that is utilized to manipulate the qubits within their systems.

Perceivably, the primary goal of quantum computing is the establishment of quantum computers capable of solving complex problems faster than traditional computers. Commonly all quantum computers use qubits to process information, whereas classical computers only use bits. A bit, or binary digit, is the smallest unit of data that a computer can process. A bit is always in one or two definite physical states and these states are usually represented by a 0 or 1. Quantum bits are most commonly referred to as qubits, and qubits can simultaneously exist in multiple states, which is known as a phenomenon called superposition.

The prominently prevalent problem that is persistently associated with quantum computers is decoherence. Decoherence is essentially the loss of information within a system, or an error in quantum computing. Decoherence is most often caused by the following: radiation from nearby warm objects, the unwanted interactions between qubits, as well as changes in the magnetic and, or electrical fields. In ion trap quantum computers, the qubits used by the system are literally ions trapped by electric fields and then manipulated with lasers. The physical embodiment of ion traps usually consists of silicon sheets, or aluminum sheets, that externally encased by layer of gold (4), and this information is consistent among all modern ion trap quantum computers. However, my invention is extremely more complex than both its silicon-based and aluminum-based ion trap counterparts. The application of my invention compliant with ion trap quantum computing bears its presumable capacity of potentially leading to monumental advancements within the ion trap quantum computing field. When properly assembled contingent upon my explicit instruction, the characteristics illustrated by the separate components used to construct my invention derives an acknowledgement that the decoherence commonly associated with ion trap quantum computers is potentially, drastically, decreased; or that this said decoherence has potential to be substantially relinquished through employing my invention as the quantum computing system's ion trap. The only acknowledged prior art distinctly associated with the proposed materials incorporated in my invention is not as correlated with my invention as previously assumed. I ascertained awareness of explicit denotation regarding this said prior art disclosed by the Delta Institute of Theoretical Physics publication within the Science Daily Journal; in which this publication suggest mercury telluride (1) structures, capable of use for the same said purposes (as my proposed invention), whereupon these said mercury telluride (1) structures have already been modeled and are theoretically possible, but they have yet to be synthesized. In actuality, precise comprehensive research and analysis reveals that these said structures postulated by the Delta Institute of Theoretical Physics within this cited article, do not genuinely correspond with my invention. My invention includes two separate identical mercury telluride (1) layers that create an adjoining parallel encasement around a central graphene (2) layer, in which this central graphene (2) layer is integrated with superfluid helium-4 (3); meanwhile the hypothetical structures presented by the Delta Institute of Theoretical Physics just merely arrange nanocrystals of mercury and tellurium into a honeycomb structure. Their presumed atomic mercury and tellurium hexagonal honeycomb structure is identical to the atomic disposition of the atoms found in graphene (2). I feel as if this particular publication is not directly considerable prior art related to my invention, since my invention explicitly consists of two distinctly separate identical mercury telluride (1) layers incorporating a single central layer of graphene (2). The Delta Institute of Theoretical Physics' research however does not incorporate the independent physical inclusion of either graphene (2) or mercury telluride (1) layers. The concluded research regarding the Delta Institute's theoretical structures, demonstrates that these said theoretical structures are only a hypothetical atomic arrangement of mercury and tellurium nanocrystals mimicking the hexagonal lattice atomic structure of graphene (2). This specific publication did not disclose any evidence pertaining to the Delta Institute of Theoretical Physics intentions of potentially constructing any fabrication including mercury telluride (1) being physically integrated with graphene (2).

### BRIEF SUMMARY OF THE INVENTION

The essential purpose of my invention is to immensely reduce the decoherence commonly associated with ion trap quantum computers, in which my invention presumably bears a conceivable capacity to potentially eliminate decoherence altogether. My invention explicitly consists of the unambiguous assemblage of mercury telluride (1), graphene (2), and superfluid helium-4 (3). Two separate identical sheets, or layers of mercury telluride (1) are used in bilaterally confining a single central graphene (2) layer. This said central graphene (2) layer is formable incorporating multiple individual graphene (2) sheets stacked parallel to one another. An alternative to stacking independent graphene (2) sheets to form the finished central graphene (2) layer of my invention, is to chemically grow this central graphene (2) layer to a desired thickness independently suitable for various specific applications. After this finished central graphene (2) layer is bilaterally adhered and encompassed between the two separate identical mercury telluride (1) layers, then the entire exterior of said composition is externally encased within a layer of gold (4). The advisable ideal thickness of the central graphene (2) layer as well as the suitable ideal thicknesses of the two separate identical mercury telluride (1) layers is ulteriorly mentioned in this disclosure but the amount of superfluid helium-4 (3) along with the length and width of those respective layers are to be determined specifically catering to the individual system that employs my invention.

There are currently only two known types of ion traps equipping the ion trap quantum computers used today and the individual composition of each of these said types of ion traps independently consists of only a layer of a single element sheathed within a layer of gold (4). Some of the modern ion trap quantum computers employ a silicon layer wrapped in a layer of gold (4), while the others employ an aluminum layer also wrapped in a layer of gold (4). The respective independent cost to individually manufacture either one of these primitive silicon-based, or aluminum-based ion traps is relatively appraised in the hundreds of thousands of US dollars. Perceivably, the decoherence prominently displayed by designs of each the silicon-based and the aluminum-based ion trap are due to the simplicity of the composition of both those particular ion traps. No conspicuous characteristics arise indicating any advantages of an ion trap quantum computer employing either the silicon-based or aluminum-based ion traps. This perceived discernment attains validation derived from the short life span demonstrated by the ions utilized and manipulated within these said ion trap quantum computers equipped with the silicon-based or aluminum-based ion traps.

The final incremental step of the procedure in implementing a fabrication of a completely functional ion trap prototype of my invention involves a practical integration regarding gradually introducing, accurately transporting, and precisely administering available preexisting superfluid helium-4 (3) already present within any ion trap quantum computing system equipped with my invention, essentially transferring this said superfluid helium-4 (3) directly into the central graphene (2) layer included in my invention. The preeminently available option concerning introducing superfluid helium-4 (3) into this central graphene (2) layer of my invention is incorporating the use of microfluidic channels (6). The external encompassing layer of gold (4) enclosing a complete fabrication of my invention comprehensively confines the internally available superfluid helium-4 (3) present within my invention and this said confinement essentially traps the superfluid helium-4 (3) within my invention. This proposed confinement of the superfluid helium-4 (3) present within an ion trap quantum computing system employing my invention as its ion trap, literally compels the constructive integration including this preexisting available superfluid helium-4 (3) being transferred, introduced, and accurately administered into the central graphene (2) layer of my invention. Relevant prior art predominantly acknowledges that superfluid helium-4 (3) naturally tends to form a layer on single graphene (2) sheets in lieu of the superfluid helium-4 (3) actually infusing with the graphene (2). My invention proposal implicitly instructs the inclusion of a graphene (2) layer that is thicker than a single sheet of graphene (2), as well as including the incorporation of an external layer of gold (4) to encompass the entire exterior surface of a finalized prototype persistent with the ion trap embodiment of my invention. These two facts aid in diminishing the relevance of this said prior arts potential association with my invention. Using a graphene (2) layer that is thicker than an individual sheet of graphene (2), and then encasing the finalized structure of my invention, potentially leads to the constructive and cooperative integration of the superfluid helium-4 (3) with the central graphene (2) layer included within my invention. Considering the individual graphene (2) sheets assembled in the formation of the finished graphene (2) layer of my invention, if the deliberate arrangement of those said individual layer of graphene (2) sheets is closely spaced; this derives probability that intentionally arranging approximate close spacing between these said individual graphene (2) sheets establishes the potential capability to lead the presently available superfluid helium-4 (3) to quasi-two-dimensional superfluid behavior, meaning the helium atoms would move collectively across the confined space provided within the graphene (2) layer. Considering that the spacing between the independent graphene (2) sheets comprising a thicker finished graphene (2) layer is compatible to the atomic size of helium atoms, in which helium atoms are around 0.256 nanometers in diameter; then the presented helium atoms employed within the finalized graphene (2) layer of my invention bear capacity to predictably form interlayer films between those individual graphene (2) sheets, in addition to this helium forming layers on the surfaces of those same individual graphene (2) sheets. The temperature and pressure employed within this proposed system equipped with my invention, directly influences the phase transitions of the confined helium present within this said system. At extremely low temperatures, the provided helium made available with this system possesses the capability of undergoing a transition into its superfluid phase, and this transition induces a variation of perceivable behaviors expected to be exhibited by this said helium. This superfluid transition of helium is directly correlated with the increase of pressure provided within this system, and all this information concerning the behavior of helium being integrated with graphene (2) is primarily dependent upon the confined geometry established by the structure containing this said helium.

I rationally consider my invention advantageous compared to the silicon-based or the aluminum-based ion traps currently used in ion trap quantum computers, due to the individual intricate properties associated with the materials included in my invention. Giving substantial consideration concentrated on graphene's (2) exceptional ability to transfer electrical signals, and then coupling that factuality with the exceptional electrically conductive surface associated with mercury telluride (1) along with the peculiar insulating bulk of mercury telluride (1), the anticipation of novel contemplations arises from the potential capacity attributable the absolute assemblage of a complete prototype enabled as the ion trap embodiment of my invention. Introducing superfluid helium-4 (3) directly into the central graphene (2) layer of my invention effectively reinforces my invention's ability to manipulate electrical signals deliberately, accurately, and diversely. General knowledge currently accepted within the field of quantum computers undoubtedly identifies the fact that superfluid helium-4 (3) is invariably incorporated and utilized by every type of quantum computer today. The preexisting presence of superfluid helium-4 (3) in all quantum computers, specifically including ion trap quantum computers, ensures that minimal extra steps are required relating to integrating superfluid helium-4 (3) directly into the central graphene (2) layer included in my proposed invention. Fabricating microfluidic channels (6) to successfully transport, and to gradually inject superfluid helium-4 (3) directly into the central graphene (2) layer of my invention, is the only supplemental step pertaining to accurately integrating and precisely administering the transfer of superfluid helium-4 (3) directly into the central graphene (2) layer my invention: especially considering the commonly accepted acknowledgement concerning the preexisting availability of superfluid helium-4 (3) included in all ion trap quantum computers of today.

### BRIEF DESCRIPTION OF THE DRAWINGS

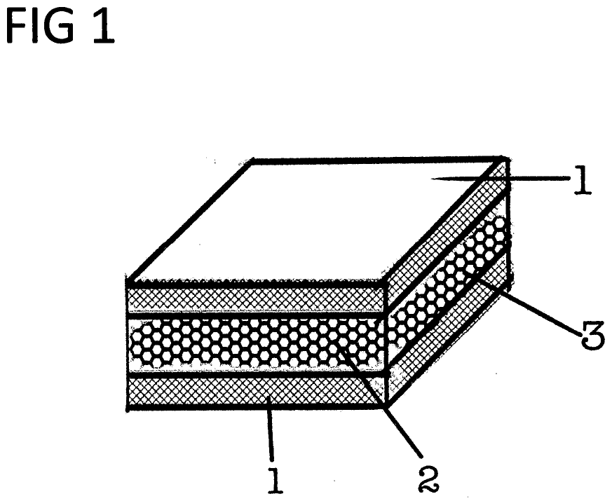

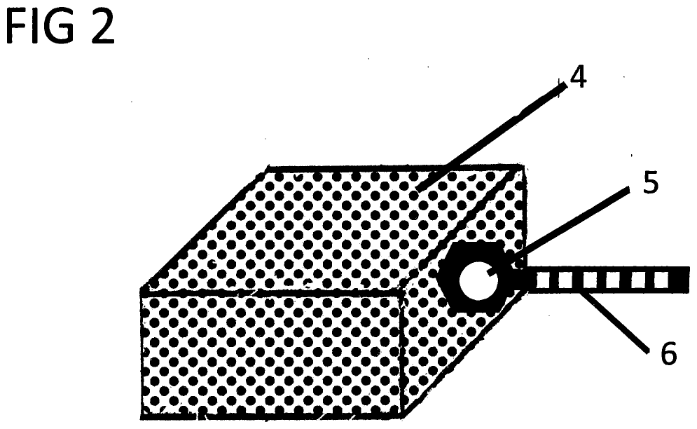

Essentially, my invention distinctively consists of only three constituents, and they are graphene (2), mercury telluride (1), and superfluid helium-4 (3); the preferred front-page view is FIG. 1 and FIG. 1 illustrates this primary structure. The externally encompassing layer of gold (4) intended to encase the entire exterior surface of my invention is demonstrated by FIG. 2 and this enclosing layer of gold (4) is consistent with the persistent unmitigated fact that currently all ion traps equipping modern ion trap quantum computers are intentionally designed incorporating a finalized enclosure comprised of a layer of gold (4). FIG. 2 also displays a hermetic seal (5), or hermetic sealing mechanism (5), as well as a microfluidic channel (6). Referring to the incorporation of the FIG. 1 drawing contemporarily submitted within this particular disclosure of my invention: mercury telluride (1) is represented numerically with the number 1, whereas graphene (2) is represented numerically with the number 2, and the number 3 is used in representing superfluid helium-4 (3). The internally located central graphene (2) layer is illustrated with a reoccurring hexagonal pattern, in which this reoccurring hexagonal pattern was uniquely applied resembling and distinctly implementing the fact that the atomic structure of graphene (2) is also precisely arranged in a hexagonal lattice. The crosshatching pattern illustrating the separate identical mercury telluride (1) layers was used to intentionally aid in differentiating the two separate identical mercury telluride (1) layers from the central graphene (2) layer. Specifically referring to the central graphene (2) layer illustrated in FIG. 1, all the internally established and centrally located open “white” areas established within the interiors of the “black” lines that form the reoccurring hexagonal structure; it is suitably implied all these open “white” areas implicitly represent the presence of superfluid helium-4 (3) within the system. FIG. 2 illustrates the external layer of gold (4) intended to encase the entire exterior surface of primary structure indicated by FIG. 1, in which this said layer of gold (4) is represented numerically with the number 4. This externally encasing layer of gold (4) is illustrated in FIG. 2 through the employment of a primary rectangular prism resembling dimensions congruent to the dimensions of the rectangular prism structure illustrated by FIG. 1, except that each face of this said rectangular prism displayed by FIG. 2 delineates a repeating pattern of black circles, or dots. This repetitive pattern of black circles displayed with FIG. 2 implicitly represents the exterior surface layer of gold (4) enclosing the primary structure of FIG. 1. Additionally, FIG. 2 incorporates a hermetic seal (5) illustrated with the black hexagon enclosing a white circle; FIG. 2 also incorporates a microfluidic channel (6) represented with a thick black line that includes white spaces in intervals. The microfluidic channel (6) of FIG. 2 is directly adjoining the surface of the primary structure in which this microfluidic channel (6) specifically connects to the area bearing the hermetic seal (5).

### DETAILED DESCRIPTION OF THE INVENTION

The following sections reproduce relevant parts of the detailed description from U.S. application Ser. No. 18/171,610, filed on Mar. 6, 2023:

The properties of the three components that are in my invention would lead one to believe that an electrical signal can pass through the interior of this tri-layer with little to no resistance. The first component would be the mercury telluride (1), which normally comes in powder form or in pellets. Mercury telluride (1) is a semiconductor with an insulating bulk, meaning it's electrons specifically collect on its exterior. This is the basis of my tri-layer because of the insulating bulk. It is almost as if electrons skip traveling through mercury telluride (1)'s bulk and just appear on its surface. Since I am proposing that my invention will replace the current gold (4) wrapped silicon quantum processor computer chips, it may be worth considering that mercury telluride (1) naturally occurs in gold (4) deposits in nature. This fact possibly means that the mercury telluride (1) of my invention would positively interact with gold (4) if it were to be wrapped in gold (4) and to be used as an ion trap in a quantum processor. The next solid component of my tri-layer is graphene (2), which is a single layer of carbon atoms arranged in a hexagonal lattice structure. Graphene (2) is semiconductor and so is mercury telluride (1) so I believe that these two compounds will interact productively. Graphene (2) also has properties that allow for its electrons to move freely across the graphene (2) layer. It is common knowledge that graphene (2) is in a vast majority of today's touchscreen devices, which proves its potential to carry electrical signals extremely well. The last component of my invention is simply the addition of superfluid helium-4 to the interior of my invention. Superfluid helium-4 flows with zero resistance and no friction. This fact makes superfluid helium-4 the perfect candidate to improve the efficiency of graphene (2)'s already great ability to transfer electrical signals. When this entire system is assembled, a near frictionless environment is created within the tri-layer, for electrical signals to be carried through. The insulating bulk of mercury telluride (1) already allows for effortless electron flow and the addition of superfluid helium-4 will only amplify this. The graphene (2) would carry the electrical signals in this environment, that could theoretically lack electrical resistance. The solid components of my tri-layer invention are very easy to manufacture. Graphene (2) is a thin layer of carbon that must be carefully laminated in between two separate mercury telluride (1) sheets. When wrapped in gold (4), my invention, could serve as more of a superior alternative to the simple, silicon wrapped in gold (4), chips that are currently used today in the ion traps of some quantum computers.

Editing entails the following changes and additions being made to the detailed description section of the parent application: the term “frictionless bi-layer” was changed to “invention,” bilayer was replaced with tri-layer, and the phrase “pressed, with extreme pressure,” was replaced by “carefully laminated,” as well as the deletion of the statement “or the graphene (2) could be pressed directly with the mercury telluride (1) in powdered form.” The sentence, “Adding superfluid helium-4, which has a temperature requirement of almost 2Kelvin, could potentially be an obstacle for ordinary physicists when trying to replicate this experiment,” was also removed in entirety, from the original disclosure of the written description of the invention section in the previously filed parent application.

### New Matter:

Various deficiencies were identified within the disclosure of the previously submitted parent application, justifiably inducing the conception of this disclosure. Introducing new matter warrants its inclusion into this specific disclosure stemming from those deficiencies found in the parent application. Essentially, the purpose this disclosure intends to address, is satisfying the enablement requirements compliant with legal utility patent applications. Due to a spontaneously abrupt and extreme primal excitement induced from an elating realization of the monumental capacity potentially demonstrated through employing my theorized invention, in which this hasty elation adversely coupled my lack of knowledge pertaining to the explicit compliance policies established by the USPTO regarding utility patent application processes, requirements, and formatting. These previously stated facts influenced and directly contributed to the numerous inadequacies unearthed with the disclosure of my initial patent application, as well as the inadequacies revealed in my subsequent amendment attempts. The following introduction of new matter caters to the various constituents regarding the enablement of my invention. Disclosing this information including new matter substantially provides in-depth insight on graphene (2) in correlation with independent separate details relating to preparing and producing a desirable finished graphene (2) layer bearing an approximate thickness greater than the D thickness of a single graphene (2) sheet. Additionally providing detailed information acknowledging the properties attributed by mercury telluride's (1) is included with precise instructions in properly preparing and producing desirable finished mercury telluride (1) layers. How to integrate the central graphene (2) layer through directly introducing it with superfluid helium-4 (3) is also addressed within this disclosure. Explicit enunciation of incremental procedural steps in accurately assembling a laminate consisting of an adherence between a central graphene (2) layer bilaterally encompassed with two separate identical mercury telluride (1) layers. The recommended pressure and temperature requirements to laminate this central graphene (2) layer in between the two separate identical mercury telluride (1) layers is also discussed within this disclosure. Initially, an exposition pertaining how each of the individual constituents included in my invention independently function, and how these said constituents interact cooperatively, holds grounds for commencing the new matter provided by this disclosure. A revelation deriving the presumable function of each the elements included in a completed prototype of my invention upon its finalized assembly is mentioned as well within this disclosure.

The inception of newly introduced matter initiates with necessary precursory information regarding graphene (2). Graphene (2), by definition, is a single layer of carbon atoms that are atomically arranged in a hexagonal lattice, and the arrangement of the atoms resemble a honeycomb structure. A single sheet of graphene (2) is approximately 0.34 nanometers thick. Graphene (2) is prominently known for is ability to exceptionally carry electrical signals. Graphene (2) also boasts a high resistance, which is precisely calculated to be 200 times more resistant than steel, while additionally being 5 times lighter than aluminum. Some more diverse properties of graphene (2) include its high thermal and electrical conductivity, elasticity, and toughness. The recommended thickness of the graphene (2) layer being incorporated into my invention is 3 to 10 nanometers. Since a single sheet of graphene (2) is only 0.34 nanometers thick, it is suggested that multiple graphene (2) layers are used to reach the desired thickness of 3 to 10 nanometers. Ideally, 3 to 10 graphene (2) layers would suffice as a starting point in constructing my invention, in which this approximation could later be specifically tailored to accommodate the specific individual system that the invention is employed in.

There are four fundamental processes used to construct graphene (2) layers that are thicker than a single sheet of graphene (2). These processes are as follows: layer by layer assembly, chemical vapor deposition, mechanical exfoliation, and chemical exfoliation. I advocate the use of chemical vapor deposition, specifically using copper as the substrate. This process involves using high temperatures to decompose a carbon-containing gas, such as methane, on a substrate, in which the preferred substrate is copper. Accurately controlling the deposition time and the gas flow rates is imperative in producing high-quality graphene (2) sheets constituting a graphene (2) layer of the desired thickness. A class 1000 clean room is obligatory to provide the necessary conditions for creating a graphene (2) layer that is 1 to 10 nanometers thick. To produce this said graphene (2) layer, a class 1000 cleanroom is a necessity, not an implication; and employing a class 1000 cleanroom minimizes the possible contamination of the graphene (2) layer produced. Manufacturing this desired graphene (2) layer incorporates employing an environment consistent with the presence of a controlled atmosphere. This controlled atmospheric environment is also an essential requirement crucial in the prevention of oxidation of the materials used to created this said graphene (2) layer. This controlled atmosphere might involve using a vacuum chamber or using an inert gas environment, whereas argon or nitrogen are potential gas options.

There are precise procedural steps concerning utilizing the recommended chemical vapor deposition method, in which they are appurtenant to the procedure for synthesizing graphene (2), leading to the creation of a graphene (2) layer commemorating the desired thickness for intentional inclusion in my invention. The first step of the chemical vapor deposition method is to prepare a copper substrate to be used as a catalyst for graphene (2) growth. Next, this substrate is placed in a chemical vapor disposition furnace and then this furnace is heated to approximately 1000° Celsius. Heating the substrate in conjunction with hydrogen gas is necessary to remove any surface oxides present. Introducing a calculated amount of a methane and hydrogen gas mixture into the system, is the ensuing step. The advocated elevated temperatures will cause the methane to decompose, and this results with the deposition of carbon atoms onto the (copper) substrate. Repeating this process of depositing carbon atoms onto the (copper) substrate is done until the finished formation of a graphene (2) layer demonstrating the desired thickness. The last step of this chemical vapor deposition process is to gradually cool the furnace, while simultaneously maintaining a flow of hydrogen gas to prevent oxidation.

After successfully employing the chemical vapor deposition procedure to manufacture the desired graphene (2) layer bearing an approximate thickness of 1 to 10 nanometers, the subsequent step in fabricating a prototype of my invention is to prepare that said graphene (2) layer for transfer. The wet transfer technique is the best predicted method for transferring this graphene (2) layer. This technique commences with spin-coating a layer of poly(methyl methacrylate) onto the graphene (2)/copper substrate. Copper etching is the next step of this wet transfer technique, in which copper etching is attainable by immersing the entire graphene (2)/copper substrate into an ammonium persulfate solution. Potentially, this will yield a graphene (2)/poly(methyl methacrylate) film floating on the surface of the ammonium persulfate solution. To remove the etchant residue, the succeeding step is to wash the graphene (2)/poly(methyl methacrylate) film by rinsing this said film with deionized water. Transferring the graphene (2)/poly(methyl methacrylate) film onto a temporary substrate is the following step, in which it is imperatively advisable to utilize a silicon dioxide/silicon wafer as this preferred substrate. The last procedural step of the wet transfer technique requires the use of acetone to remove the poly(methyl methacrylate) layer, and this results in leaving the graphene (2) layer attached onto the temporary (silicon dioxide/silicon wafer) substrate. This information concludes the details specifically concerning graphene (2) and this information is proceeded with directives appertained to mercury telluride (1) and the procedural requirements in forming mercury telluride (1) layer(s).

By precise definition, mercury telluride (1) is a binary chemical compound of mercury and tellurium. Mercury telluride (1) is a superconducting semi-metal, and it was first discovered in 2007. Mercury telluride (1) also was identified as the very first topological insulator. A topological insulator is a material whose interior behaves as an electrical insulator while its surface behaves as an electrical conductor. These properties equate to electrons only being able to move along the surface of the topological insulator. Particularly, mercury telluride (1) occurs naturally in the mineral form known as coloradoite. Coloradoite is a rare telluride ore, in which a telluride is derivative of the element tellurium. Tellurium is commonly associated with metallic deposit. Referring to the explicitly mentioned statements disclosed within the Detailed Description of the Invention section of my previously disclosed patent application, begets me reiterating the fact that gold (4) naturally occurs within mercury telluride (1) deposits. This certitude is exceptionally relevant concerning my invention, since a completed prototype of my invention requires an external encasement consisting of a thin layer of gold (4). Incorporating my invention with this said external encasement of a layer of gold (4) is contingent with the current ion trap designs employed within ion trap quantum computers. It is perceivable that a finalized prototype of my invention will demonstrate desirable positive interactions between the adjoining of both separate identical layers of mercury telluride (1) being respectively adhered to the external layer of gold (4) that encloses my invention.

Prior to introducing the elaborate procedure required to create a layer of mercury telluride (1), I will list some of the unique properties of mercury telluride (1). These unique properties of mercury telluride (1) collectively lead to its selection as one of the predominantly fundamental materials included in my invention. Before describing the properties of mercury telluride (1), I find it slightly imperative to state the various forms or phases in which mercury telluride (1) exist. Usually, the powered form of mercury telluride (1) is attainable through the processing and refining of coloradoite ore. The most notable and salient form of mercury telluride (1) is its crystalline form, which attributes a zincblende crystal structure. This zincblende crystal structure is a type of cubic crystal lattice and this distinct crystalline structure is what gives mercury telluride (1) its semiconducting properties. Particularly, the arrangement of atoms constructing this crystal lattice allows for governing the precise guidance and manipulation of electrons. The crystalline form of mercury telluride (1) is typically acquirable through one of two methods: either by using the chemical vapor deposition or through using molecular beam epitaxy. Both these methods involve strategically controlling the deposition of mercury and tellurium atoms on a substrate under specific conditions, resulting in the growth of a crystalline structure illustrating desirable properties. An amorphous form of mercury telluride (1) also exists, as well as a form concerning the synthesis of mercury telluride (1) into nanoparticles. Superconductivity is not archetypically associated with neither the nanoparticles form of mercury telluride (1), nor with the amorphous form of mercury telluride (1).

There are several unique properties exhibited by mercury telluride (1) that are specifically related to the movement of electrons. Mercury telluride (1) evinces an insulating bulk, which is most commonly associated with topological insulators. In the context of topological insulators, an insulating bulk refers to the interior region of that material not allowing the conduction of electricity. This insulating region is vital in providing the distinctive characteristics observable at the materials surface. Electricity, explicitly electricity on the surface is conducted in a highly efficient and protected manner due to the topological nature of this insulating bulk. This insulating bulk plays a significant role in influencing the surface properties attributed to a topological insulator; the insulating bulk essentially acts as a barrier that prevents the scattering of electrons within the material. The protected conductive surface states that are typically associated with topological insulators, are primarily attainable due to the presence of this interior insulating bulk providing this said referred symbolized barrier. This insulating bulk establishes conditions that allow electrons to flow along the surface of the topological insulating material, in which these electrons flow anomalously and efficiently. The insulating bulk simultaneously preserves the material's topological properties while electrons flow along its surface. This insulating bulk region in topological insulators ensures the flow of surface electrons by shielding those said electrons from disturbances produced inside of the material. The special conductive surface properties commonly attributed by topological insulators receive protection that is provided from the implied barrier established by its insulating bulk. These said surface states are notably protected by time-reversal symmetry, whereas this protection optimally manifests robust edge states where electrons move without backscattering, thus reducing energy dissipation. Pure mercury telluride (1) is a zero-gap semiconductor, and this fact substantially leads to the high electron mobility of mercury telluride (1) as well as revealing idiosyncratic transport properties. The next notable feature that mercury telluride (1) exhibits is the quantum spin Hall effect, specifically identifiable within a two-dimensional quantum well structure. A two-dimensional quantum well structure employs inducing an applied electric field to cause spin-polarized edge currents, and this effect locks the electron spin to its momentum. Band inversion is another unique characteristic of mercury telluride (1). In mercury telluride (1), the conduction band and valence band can invert under certain conditions, and this inversion has significant implications for electron transport properties. In addition to the previously mentioned traits of mercury telluride (1), there are two additional traits of mercury telluride (1) worth mentioning, which are magnetoresistant and high electron mobility. High electron mobility, attributed with mercury telluride (1), is due to the linear dispersion relation to the Dirac point, as well as the low effective mass of electrons. Insight on magnetoresistance concludes information pertaining to the unique properties of mercury telluride (1). Mercury telluride (1) displays strong magnetoresistance effects, and these effects are demonstrated in direct correlation to mercury telluride's (1) resistance changing significantly in response to an applied magnetic field. The accumulation of these previously cited properties that are affiliated with mercury telluride (1) significantly contributed to the inception of my selection of mercury telluride (1) as the fundamentally predominant material included within my invention. These said properties of mercury telluride (1) were drastically pivotal in my decision to appoint mercury telluride (1) as the favored material to bilaterally encompass the central graphene (2) layer of my invention.

For the initial production of a mercury telluride (1) layer, I personally advocate using the molecular beam epitaxy technique. The molecular beam epitaxy technique is substantially preferable, considering the goal is to produce multiple individual identical layers of mercury telluride (1), consistent with each of these layers bearing dimensions constituting a favorable thickness of 10 to 100 nanometers. Conformant with my invention's potential ion trap embodiment that is catered towards an ion trap quantum computer being equipped with my invention as its ion trap, the desired final thickness of each solitary layer of mercury telluride (1) included in my invention; whereas this desired thickness can later be systematically revised and modified, specifically catering to the desired results of this individual said ion trap quantum computer that employs my invention as its ion trap. Molecular beam epitaxy is a precise technique used for growing thin films and nanostructures. The first step of utilizing this procedure to grow two individual identical mercury telluride (1) layers that each bear a preferred thickness, whereas this first step is unquestionably “preparation”. Along with initially preparing the preferred substrate, preparing the molecular beam epitaxy system being habituated in the formation of these two said identical layers of mercury telluride (1) is also necessary. Choosing a suitable substrate is the precluding step to employing the molecular beam epitaxy technique used in growing two identical distinct layers of mercury telluride (1), in which each of these said layers consist of uniformly indistinguishable dimensions. The preferred substrate choice should be established based upon the analysis of which substrate suitably matches the lattice constant of mercury telluride (1), while choosing this substrate is completed conjunctively with the consideration to producing results contingent with the reduction of strain and defects. Two considerably predominant substrate options exist, in which these options are gallium arsenide and zinc telluride. Following my conduction of deliberate, and extensive research and investigation regarding how to effectively produce a mercury telluride (1) layer yielding a thickness of 10-100 nanometers, whereas this information arouses a drastically crucial revelation concerning the importance of the individual lattice constants attributed by the materials involved. The approximate lattice constants of these materials are as follows: mercury telluride (1) has a lattice constant of 6.46, gallium arsenide has a lattice constant of 5.65, and zinc telluride has a lattice constant of 6.10. Lattice mismatch is calculated with the formula: lattice mismatch equals the lattice constant of the substrate minus the lattice constant of the epilayer and then that result is divided by the lattice constant of the epilayer. These derived results, then are, multiplied by 1. Acknowledging that the epilayer is mercury telluride (1), in this case. These calculations provide evidence determining that zinc telluride has a significantly lower lattice mismatch with mercury telluride (1), in comparison to the lattice mismatch of gallium arsenide with mercury telluride (1). The last step of preparing the substrate employed in growing a mercury telluride (1) layer bearing an approximate thickness of 10-100 nanometers, is to simply clean the substrate.

Cleaning the substrate, is typically accomplishable by using solvents, using ultrasonic cleaning, and/or with conjunctively using chemical treatments. All these cleaning methods are completed contingent with the intended purpose to removing any organic or inorganic contaminants from the substrate. It is highly recommended to use a combination consisting of each of these mentioned cleaning methods, as well as using the plasma cleaning method strictly after the substrate has been properly dried. It is thoroughly advisable to use an amalgamation including the employment of every one of these cleaning methods. This is critical for achieving high-quality epitaxial growth, as well as reducing defects aroused in the subsequential layers produced. The purpose of using the solvent cleaning technique to clean the substrate, is to remove organic contaminants such as oils, greases, and residues. Completing this process is attainable by sequentially immersing the substrate in high-purity solvents such as acetone following this immersion in acetone with rinsing the substrate in isopropyl alcohol. Ultrasonic cleaning has an intended purpose to dislodge the particles from the substrate's surface, along with dislodging any remaining organic contaminants present on the substrate's surface. This process is accomplishable, and it is also consistent with employing the use of an ultrasonic bath that is comprised of acetone and isopropyl alcohol. Ultrasonic cleaning also ensures the removal of small particles and residues through cavitation. Using chemical treatment comes next, and this has the intended purpose to remove any residual oxides and surface contamination that remain as a resultant from the process involving the previously listed substrate cleaning steps. This said chemical treatment consists of etching the substrate in a mild acid solution, which involves dipping the substrate in a solution of hydrochloric acid, specifically hydrochloric acid that is diluted with deionized water. Ferric chloride is also a potential alternative etchant option. After this acid treatment, one should then thoroughly rinse the substrate with deionized water to remove any residual acid. Prior to conducting the final step of cleaning the substrate, in which this final step is to perform plasma cleaning on the substrate, rinsing and drying the substrate is completed before performing the plasma cleaning. Finally, the rinsing and drying steps inherent in this cleaning process have the intentional purpose of removing the remaining cleaning agents, and to also dry the substrate without leaving water spots or residues. Particularly, the purpose of this step in the cleaning process involves rinsing the substrate with deionized water following each cleaning step. Drying the substrate warrants using a nitrogen blow-off, in which incorporating this nitrogen blow-off will aid in avoiding the formation of watermarks. Lastly, plasma cleaning requisites to further remove any organic residues and this is conducted in supplement with improving surface cleanliness of the substrate. Plasma cleaning involves exposing the substrate to an oxygen plasma and this enhances the comprehensive cleanliness of the surface, by removing any remaining organic contaminants. Integrating and employing a collaborative combination of each of these said cleaning methods in the explicit sequential order circumspect with how they are incrementally listed ensures the finalized zinc telluride substrate is as clean as possible. The next procedural step inclusive in preparing the molecular beam epitaxy system simply consists of loading the source materials, namely mercury and tellurium. Respectively loading mercury and tellurium into the system, ensues with the deliberate calibration of this molecular beam epitaxy system. Calibrating the molecular beam epitaxy system incorporates using effusion cells, or thermal sources for mercury and tellurium, and conducting these calibrations guarantees precise control over the system's flux rates.

Physically growing a desirable mercury telluride (1) layer is the next step of this growth process. There are only two sequential steps following the mercury telluride (1) layer growth procedure in which those two sequential steps include undergoing various post-growth requirements and this is succeeded by performing troubleshooting of the molecular beam epitaxy system being employed to grow the mercury telluride (1) layer. Appropriating the parameters of these final two sequential steps is all based upon the analysis of the derived data results and applying this information effectively leads to the optimizing this said system. The first step of the mercury telluride (1) layer growth process involves evacuation, and this includes ensuring the molecular beam epitaxy system establishes an environment that bears ultra-high vacuum conditions. Ultra-high vacuum conditions typically range in 10-10 Torr. These ultra-high vacuum conditions provide an environment that minimizes contamination and allows precise control over the deposition process. After the vacuum conditions are satisfied, heating the substrate is the next step in growing a mercury telluride (1) layer. Heating the substrate to the desired growth temperature, which for mercury telluride (1), is approximately between 200° and 300° Celsius. Meticulously accurate temperature control is indispensable for uniform growth of the substrate. Epitaxially growing the mercury telluride (1) layer is the last step of the growth process, wherein an inflexible ratio of mercury and tellurium is imperative. Calibrating the flux rates of mercury and tellurium is the inaugural step of this portion of the mercury telluride (1) layer growth process. Deliberate flux rate calibrations allow the ability to precisely regulate the forming of a desirable finalized mercury telluride (1) layer demonstrating the appropriated thickness of 10 to 100 nanometers. Mercury has a flux rate ranging from 106 to 10-10 Torr, meanwhile the flux rate range of tellurium is 10-7 to 106 Torr. Typically, the effusion cell temperature of mercury would range from 180° to 220° Celsius, and the effusion cell temperature of tellurium would range from 300° to 350° Celsius. The molecular beam epitaxy system should be calibrated cogitating these given optimal flux rates. When employing the use of a molecular beam epitaxy system to form a mercury telluride (1) layer, it is worth noting the necessitated ratios of mercury and tellurium, in which the ideal ratio is 1:1. Using this molecular beam epitaxy system presumably presents a mandate to introduce an excess of mercury into this system, resulting in a favorable stoichiometric composition. Due to the high volatility of mercury, this particular procedure demands using an excess amount of mercury in order to compensate for some of the mercury expected to be loss during the growth process. Growing a desirable mercury telluride (1) layer appropriates using the demanded flux ratio of mercury to tellurium which is respectively 1.5 to 2.1. The archetypal growth rate for high-quality mercury telluride (1) layers is approximately 0.1 nanometers per minute. Adjusting the flux rates during the physical formation of the mercury telluride (1) layer is essential in achieving this preferable growth rate. Maintaining a low background pressure (better than 10-9 Torr) within the molecular beam epitaxy system's growth chamber is essentially substantiated to prevent contamination. This preceding information establishes appropriate optimal initial parameters pertaining to utilizing a molecular beam epitaxy system in fabricating a mercury telluride (1) layer and precisely incorporating an analysis of this said preceding information adequately provides and prepares a basis for initiating the deposition process to accurately grow an approximate layer of mercury telluride (1) via mercury telluride's (1) layer-by-layer growth. Monitoring this growth of the desired mercury telluride (1) layer is attainable through using an in-situ technique such as Reflection High-Energy Electron Diffraction. Accurately monitoring this growth ensures the desired finalized mercury telluride (1) layer yields correct layer structure and thickness. Real time monitoring of the mercury telluride (1) layer is acquirable upon employing a thickness-monitoring device, such as a quartz crystal microbalance. Growing a mercury telluride (1) layer approximately 10-100 nanometers thick mandates carefully monitoring this said growth in conjunction with simultaneously and precisely controlling this said growth to achieve the formation of the preferable finalized mercury telluride (1) layer. This precursory information concludes the mercury telluride (1) layer growth process, in which cooling and stabilizing the finished mercury telluride (1) layer ensues. Considering that upon successfully completing a fabrication of a desirable mercury telluride (1) layer bearing an approximated thickness ranging between 10 to 100 nanometers, whereas finalized mercury telluride (1) layer establishes the optimal conditions to commence the gradual cooling of the substrate to room temperature. Measuring the thickness of the finished mercury telluride (1) layer is potentially accomplishable through incorporating the application of multiple various techniques such as: Atomic Force Microscopy, Scanning Tunneling Microscopy, or X-ray

Reflectivity: in which using these various measuring techniques is intended to accurately verify the thickness and uniformity of the finalized mercury telluride (1) layer. Concurrently assessing the quality of the finished mercury telluride (1) layer is imperative and this said assessment is achievable through possibly applying multiple techniques, in which X-ray diffraction or Raman spectroscopy are the prevailing practical options. This previously presented information consummates the growth process in producing a desirable mercury telluride (1) layer. Next is to conduct troubleshooting of the employed molecular beam epitaxy system. This system troubleshooting is conducted in direct correlation with the analysis of the resulting data derived from utilizing this said molecular beam system. The optimization of this molecular beam epitaxy system completes the entire growth process of growing a mercury telluride (1) layer, specifically growing a 10 to 100 nanometer thick layer of mercury telluride (1). Adjusting the various parameters, such as adjusting the substrate temperature, adjusting flux rates, and or adjusting the growth time, is mandatory if the final mercury telluride (1) layer exhibits any defects. The adjustment of these parameters is coupled with fine-tuning the flux rates of mercury and tellurium, if the growth rate does not meet expectations.

Ensuing this coherent discloser of information pertaining to graphene (2) and mercury telluride (1), in which this said information concurrently includes the optimal procedures for creating a desirable layer of graphene (2) and creating desirable layers of mercury telluride (1) respectively. This disclosure infers an acknowledgment that relevant information has been attained, in which this specific information establishes a capacity of the proper preparation warranted regarding the process of assembling my invention's predominant tri-layer structure. Particularly, this said predominant tri-layer structure of my invention embodies a distinctive combination of its physical components. The novelty of laminating a graphene (2) layer between two separate layers of mercury telluride (1) is so epigrammatically unsurpassable that no relevant prior art exists. Along with employing a class 1000 cleanroom, utilizing a controlled press is also necessary to manufacture an absolute prototype of my proposed laminate comprised of a graphene (2) layer bilaterally adjoined and essentially enclosed between of two separate identical mercury telluride (1) layers. The favorable pressure applied by the controlled press lies ideally within a pressure range of 100-500 megapascals. Initially, preparing the desired layer of graphene (2) and mercury telluride (1) layers is the primary prerequisite of this laminating procedure. For fabricating the preferred layer of graphene (2) bearing a thickness ranging between 1 and 10 nanometers, along with respectively fabricating two separate identical mercury telluride (1) layers each bearing a thickness ranging between 10 and 100 nanometers, it is advisable to analyze and employ the previously provided information within this disclosure. Employing the chemical vapor deposition technique to produce a desirable 1 to 10 nanometer thick graphene (2) layer is reiterated, along with reiterating the preferable application of employing molecular beam epitaxy in producing two separate identical mercury telluride (1) layers, each bearing a thickness ranging between 10 and 100 nanometers. Specifically, regarding this laminating procedure, after accurately preparing both the identical mercury telluride (1) layers and after preparing the graphene (2) layer included this laminate, the following step is transferring this said graphene (2) layer. Transferring the graphene (2) layer begets reiteration of coating, etching, and cleaning the finished graphene (2) layer formed through chemical vapor deposition. Coating, etching, and cleaning the graphene (2) layer is all advisably conducted within an environment bearing conditions consistent with normal atmospheric pressure. These processes of coating, etching, and cleaning this said graphene (2) layer is recommendable to all be conducted using the wet transfer technique. Coating and etching this graphene (2) layer require a temperature between 20° and 25° Celsius, while cleaning this graphene (2) layer requires a temperature between 20° and 40° Celsius. As previously mentioned, the next step is to coat this completed 1 to 10 nanometer thick graphene (2) layer directly onto the preferred copper substrate by using poly(methyl methacrylate). Following this by then using ammonium persulfate, or ferric chloride to etch away the copper substrate. Next requires using deionized water to rinse and clean the poly(methyl methacrylate)/graphene (2) compound and this directly ensues the coating and etching of the graphene (2) layer. Next involves scooping the poly(methyl methacrylate)/graphene (2) compound onto a temporary substrate, in which this temporary substrate is a silicon dioxide/silicon wafer. Following this by then using acetone to dissolve the poly(methyl methacrylate) layer away from the graphene (2) layer, resulting in the desired finished graphene (2) layer left on the temporary silicon dioxide/silicon substrate. Before aligning and placing the first finalized mercury telluride (1) layer onto the central graphene (2) layer, warrants mentioning that accurately forming desirable mercury telluride (1) layers is predominantly obtainable through using the molecular beam epitaxy technique, and using this said technique includes employing an atomically flat zinc telluride substrate. The assembly of this central graphene (2) layer being independently cohered bilaterally in between each of the identical mercury telluride (1) layers, is favorably attainable through employing the same molecular beam epitaxy system used to manufacture the initial mercury telluride (1) included. Aligning the poly(methyl methacrylate)/graphene (2) combination requires the use of a micromanipulator and favorable temperature for this step ranges between 20° and 40° Celsius. To remove the poly(methyl methacrylate) away from the graphene (2) layer obliges using a solvent and acetone, or warm isopropanol being the foremost solvent options. Adhesion of the graphene (2) layer on the mercury telluride (1) layers is enhanceable through incorporating a gentle thermal annealing process. Annealing is preferably attainable at a temperature between. 100° and 200° Celsius, specifically between 150° and 200°, with this said annealing optimally occurring within an inert atmosphere, preferably an atmosphere consisting of a gas such as argon. This point of the lamination process appropriately induces the commencement of physically growing the second mercury telluride (1) layer specifically adjoining the exposed graphene (2) surface of the central graphene (2) layer of the previous resulting combination consisting of the central graphene (2) layer adhered to the initially formed mercury telluride (1) layer all obtained by the previous step. Growing this second mercury telluride (1) layer is also conducted within the same molecular beam epitaxy chamber employed in forming the initial mercury telluride (1) layer, and physically growing this second mercury telluride (1) is preferably accomplishable without removing the previously produced structure consisting of the graphene (2) layer particularly adhered to initially formed mercury telluride (1) layer. The second mercury telluride (1) layer is grown directly onto the exposed surface of the central graphene (2) layer and this second mercury telluride (1) layer is grown through incorporating the previously mentioned information relating to mercury and tellurium's respective optimal flux rates, effusion cell temperatures, growth rate, required amount of each material used, and with maintaining a low background within the employed molecular beam epitaxy system's chamber. This procedure now requires repeating the annealing process in conjunction with monitoring the growth of the second mercury telluride (1) layer. Monitoring the growth of this said second mercury telluride (1) layer being directly adhered onto the exposed surface of the central graphene (2) layer, essentially considering that this second layer of mercury telluride (1) is grown bilaterally in relation to the initially formed mercury telluride (1) layer, and monitoring this said growth of the second mercury telluride (1) layer is accomplishable through utilizing reflection high-energy electron diffraction. This concludes the advisable procedure concerning the fabrication process in manufacturing a laminate comprised of a central interior graphene (2) layer implicitly constructed directly between a bilateral enclosure of two separate identical mercury telluride (1) layers, in which conducting an inspection of this final tri-layer structure ensues. There are various techniques available for thoroughly inspecting this completed said tri-layer structure, and they include: Raman spectroscopy, atomic force microscopy, and transmission electron microscopy.

Once this tri-layer structure meets desired expectations, its entire exterior surface is then wrapped or encased within a uniform layer of gold (4). Externally enclosing the entire exterior this primary tri-layer structure of my invention with a layer of gold (4) is mandatory in making a complete prototype of my invention consistent with its intended embodiment as an ion trap and in compliance with it tactically equipping an ion trap quantum computer. This finished said layer of gold (4) preferably bears a thickness between 10 and 50 nanometers. Externally depositing a 10 to 50 nanometer layer of gold (4) directly onto the exterior of the tri-layer structure comprised of two separate identical 10 to 100 nanometer thick mercury telluride (1) layers bilaterally encompassing a central 1 to 10 nanometer thick graphene (2) layer, whereas this specific gold (4) deposition requires employing the use of a vacuum chamber equipped with: a thermal evaporation system, an electron beam evaporation system, or a sputtering system. Next is evaporating or sputtering, a uniform layer of gold (4) directly onto the exterior surface of the said tri-layer structure. Optimal parameters involved with the external gold (4) deposition onto this tri-layer structure includes the following: using a high-purity gold (4) of 99.99% of higher, using a deposition rate of 0.1 to 1.0 nanometers per second, using a low substrate temperature between 20° and 25° Celsius during deposition, and all of this is completed while simultaneously maintaining a vacuum pressure around 10-6 to 10-7 Torr. The gold (4) deposition process starts with loading the substrate into the deposition chamber and then evacuating the chamber to the desired vacuum pressure, given that this said substrate is the predominant tri-layer structure of my invention; specifically this structure includes a central graphene (2) layer that is bilaterally adhered in between two separate identical layers of mercury telluride (1). Now actually initiating the deposition of gold (4) can occur, while simultaneously using a quartz crystal microbalance to monitor the thickness of the gold (4) being deposited. After achieving the finished layer of gold (4) bearing the preferred 10 to 50 nanometer thickness intentionally incorporated to enclose the entire exterior of the primary tri-layer structure of my invention, the process of annealing this finished layer of gold (4) arises. Annealing this layer of gold (4) has three primary factors involved: temperature, environment, and duration. Ideal temperatures concerning this annealing process range between 150° and 200° Celsius, and temperature is gradually increased until reaching the target temperature. Upon attainting the target temperature, this said temperature is maintained for a duration ranging from 30 to 60 minutes. Lastly, employing the use of a vacuum, or utilizing a controlled environment bearing an inert atmosphere that consists of a gas such as argon, whereas each of these methods provide prime environments to efficiently deposit this external said layer of gold (4) intentionally encasing the entire exterior surface of the primary tri-layer structure of my invention.

The final constituent of my proposed invention is superfluid helium-4 (3), especially correlating to its integration into the intermediate graphene (2) layer included in my invention. Defining this said superfluid helium-4 (3) “integration” with the graphene (2) layer concerning my invention, explicitly insinuates using superfluid helium-4 (3) in conjunction with the graphene (2) layer. This said “integration” explicitly does not imply the infusion, nor the absorption of superfluid helium-4 (3) by the graphene (2) layer. Prior art concerning the behavior of superfluid helium-4 (3) interacting with graphene (2) states that superfluid helium-4 (3) tends to form a layer on graphene (2), or that superfluid helium-4 (3) is “adsorbed” by graphene, rather than the graphene (2) absorbing, or infusing with the superfluid helium-4 (3). Although my invention ideally consists of employing 3 to 10 stacked graphene (2) sheets that form a 1 to 10 nanometer thick graphene (2) layer, the expected behavior of superfluid helium-4 (3) on multiple stacked layers of graphene (2) is still considered to be consistent with the superfluid helium-4 (3) forming layers on the graphene (2), rather than absorbing or infusing with the graphene (2). However, the quantum effects attributed by superfluid helium-4 (3) in a confined space denotes that superfluidity of helium-4 can manifest at significantly low temperatures, due to this confinement. Spacing between graphene (2) sheets cognates with temperature in affecting the characteristics superfluid helium-4 (3) exhibits when superfluid helium-4 (3) is integrated with graphene (2). Closely spaced graphene (2) sheets could lead to quasi-two-dimensional superfluid behavior of the superfluid helium-4 (3). If the spacing between the graphene (2) sheets is comparable to the size of helium atoms, which is 0.256 nanometers in diameter, then the superfluid helium-4 (3) could potentially form interlayer films that exhibit correlated behavior across the individual graphene (2) sheets potentially forming the central graphene (2) layer included in my invention. Before elaborating on the process of integrating superfluid helium-4 (3) with the graphene (2) layer of my invention, it is necessary to mention how to physically integrate superfluid helium-4 (3) into this said central graphene (2) layer. Since the dominant embodiment of my invention intends for its employment as an ion trap within an ion trap quantum computer, it is requisite to equip that said ion trap quantum computer with microfluidic channels (6) for transporting and injecting superfluid helium-4 (3) into the central graphene (2) layer. The existing prevailing options concerning the leading suitable materials available to compose fabrications of the microfluidic channels (6) intended to transport superfluid helium-4 (3) within the system equipping with my invention are: copper, aluminum, glass (borosilicate or quartz), inconel (nickel-chromium alloy), and 304 or 316 graded stainless steel. Given the properties associated with each of these said materials derives acknowledgment that inconel is the foremost option of materials to use to compose the microfluidic channels (6) being integrated correlating with the ion trap embodiment of my invention. Ion trap quantum computers concurrently equip the environment required to host superfluid helium-4 (3), in which this said environment is consistent with the conditions manifested within an ultra-high vacuum chamber and this said environment is also consistent with the conditions present within a cryogenic chamber. All ion trap quantum computers are currently designed in conjunction with utilizing superfluid helium-4 (3), essentially all ion trap quantum computer systems are each capable of maintaining the 2.17 Kelvin temperature required for helium-4 to exhibit superfluidity. The only indispensable inclusion to an ion trap quantum computer that employs my invention as its ion trap, is to equip this said ion trap quantum computer with the previously mentioned microfluidic channels (6). Incorporating these microfluidic channels (6) into the ion trap quantum computing system provides the ability to direct and transport a precisely calculated amount of the superfluid helium-4 (3) that is already available within the ion trap quantum computer. Utilizing these said microfluidic channels (6) require that this ion trap embodiment of my invention be designed including an injection port, or injection ports that directly guide and effectively transfer the superfluid helium-4 (3) into the central graphene (2) layer. The guided transportation and injection of superfluid helium-4 (3) into the central graphene (2) layer of my invention is attainable through incorporating the use of microchannels or access points. A fully functional prototype of my invention compels that its constructed includes an incorporation of a hermetic sealing mechanism (5) that is preferably composed of gold (4), titanium, and or glass. This hermetic seal (5) is independently designed catering to the specific individual system employing my invention. The inclusion of this hermetic sealing mechanism (5) into the design and construction of my invention results in the confinement of the superfluid helium-4 (3) present and this said hermetic seal (5) also physically maintains the integrity and purity of this superfluid helium-4 (3), post-injection. The injection port, or these injection ports, and the hermetic sealing mechanism (5), are all independently tailored catering to the individual characteristics of the specific ion trap incorporating my invention. Introducing, and essentially integrating, superfluid helium-4 (3) into the central graphene (2) layer via these previously mentioned (inconel) microfluidic channels (6), is the ensuing step. This step entails using the inconel microfluidic channels (6) to guide a calculated amount of superfluid helium-4 (3) within the system, gradually transporting and then carefully administering this said superfluid helium-4 (3) directly into the central graphene (2) layer of this the system, conducted aspiring to avoid thermal shock. Adjusting this system, primarily for stabilization, is based upon the real-time data assessed, whereas this said data is derived from monitoring the system's pressure, temperature, and the amount of superfluid helium-4 (3) being administered within this system. This concludes every step regarding constructing my invention.

The best mode for carrying out my invention implements its favorable employment as an ion trap within an ion trap quantum computer. This ion trap embodiment of my invention requires the structure comprised of the superfluid helium-4 (3) integrated central graphene (2) layer that is bilaterally enclosed between two separate identical layers of mercury telluride (1), whereas the entire exterior this said structure is encased with a layer of gold (4). This gold (4) layer encasement is compliant with all ion traps currently equipped by ion trap quantum computers, and concerning my invention, this gold (4) layer encasement aids in protecting the fragile outermost mercury telluride (1) layers from the extreme cryogenic environment established as requisite for ion trap quantum computing. Ion traps compliant with ion trap quantum computers are capable of most notably exploiting the integration and employment of my invention as its said ion trap, especially considering that currently all ion trap quantum computers already equip an environment compatibly sustaining the presence of superfluid helium-4 (3). Additionally, ion trap quantum computing systems currently also provide an ultra-high vacuum, cryogenic environment desired concerning my invention. Ion traps confine ions using an electric and, or magnetic fields. The most common types of ion traps are Paul traps and Penning traps. Paul traps are frequently used in quantum computing because they provide dynamic confinement of ions by using oscillating electric fields. Paul traps typically consist of a set of electrodes that create a time-varying quadrupole electric field that confines ions radially within the Paul trap's electric field, while also simultaneously confining ions axially with a static electric field. Operating the ion trap initiates with loading ions into the trap. Loading ions into the trap is variously completable via laser ablation, electron impact ionization, or loading ions from a neutral atomic beam. The following step consists of laser cooling the ions through Doppler cooling and sideband cooling. Doppler cooling involves using lasers to cool the ions to their motional ground state by reducing the said ions kinetic energy through photon absorption and emissions processes. Succeeding sideband cooling supplements this Doppler cooling, allowing for the further cooling of ions by tuning the lasers to the red sideband of the said ion's vibrational transitions. Now the is system is ready to conduct quantum operations, whereas quantum operations consist of the following: qubit initialization and establishing quantum gates, followed by a readout of the performed operations. Qubit initialization infers initializing ions' electronic states using laser pulses to prepare the ions in a specific quantum state. Quantum gates instruct the ions on how to interact with each other and quantum logic gates are implemented using laser-induced transitions. Interactions between ions can be mediated by the ions shared motional states, allowing entanglement and multi-qubit operations. The readout of these operations is performed using fluorescent measurement, namely because specific laser frequencies cause ions in different states to fluoresce or remain dark. Observing these fluctuations are essential in assessing the ions state discrimination. Manipulating and analyzing qubit interactions is the primary goal of quantum computing, specifically ion trap quantum computers employ the use of ion traps for qubit manipulation and analysis. The structure of the components forming my invention provide a unique electrical environment, in addition to also providing surface states beneficial for ion trapping and ion manipulation, given the said properties attributed by each the components included in my invention's design. It is also worth mentioning that the layer of gold (4) encasing my invention is potentially multifunctional and can also serve as electrodes for the Paul trap and static fields. Some potential foreseen advantages regarding the primary materials utilized in the structure of my invention, consistent with its embodiment as an ion trap equipping an ion trap quantum computer are: improved thermal management exhibited in the superfluid helium-4 (3) integrated graphene (2) layer, especial electronic properties exhibited with the graphene (2) mercury telluride (1) stacked structure, and electromagnetic shielding provided by the externally encasing layer of gold (4). Thermal management is crucial for quantum coherence, electromagnetic shielding protects the ions from external disturbances while ensuring stable ion trapping conditions, and these especial electronic properties aid in electrical noise reduction while enhancing ion trap performance.

Desired favorable interactions between the materials constructing in my invention are expectable, given the individual properties of these said materials in association with electrical conductivity, derives correlated complementary cooperation allying those materials. Bestowing the precise assemblage of the deliberate materials involved in a construction of an absolute prototype of my invention, presumes the establishment of stable surface states along the exterior of this said prototype, whereas these said surface states are causally, accurately, manipulatively, and efficiently replicable along the bilateral exterior surfaces of my invention. Gold (4) is a non-reactive metal that is highly conductive, and an encasing layer of gold (4) is externally present on my invention. This enclosing layer of gold (4) is in direct contact with both exteriors of the separate identical layers of mercury telluride (1) and positive interactions between the corresponding layers of gold (4) and mercury telluride (1) is presumable, considering gold (4) deposits naturally occur within mercury telluride (1) ore. Mercury telluride. (1) bears the ability to exceptionally conduct electricity on its surface while simultaneously remaining insulating in its bulk; meaning electrons can uniquely, or manipulatively, flow along the surface of mercury telluride (1) while the internal electrons of mercury telluride's (1) bulk are concurrently confined to limited mobility. Electrical conductivity exhibited by the exterior encasing layer of gold (4) will presumably complement the electrical conductivity exhibited by each of the adjacent internal mercury telluride (1) layers, given the relative arrangement of this external layer of gold (4) encompassing the two separate identical layers of mercury telluride (1) included in an absolute prototype of my invention. Graphene (2) also attributes exceptional electrical conductivity, prompting the inclination of incorporating a centered graphene (2) layer bilaterally adjoining and essentially enclosed between the two separate identical mercury telluride (1) layers of my invention. The exceptional electrical conductivity attributed by graphene (2) arises from graphene's (2) hexagonal lattice arrangement of carbon atoms. This said hexagonal lattice allows for the formation of delocalized pi-electrons that can move freely across the entire graphene (2) structure, further allowing high electron mobility. The presence of these delocalized pi-electrons also enables rapid electron transport, additionally contributing to graphene's (2) high electrical conductivity. Strong carbon-carbon bonds presented in graphene's (2) atomic hexagonal lattice structure provides stability as well as facilitating efficient electron movement. Additionally, graphene (2) exhibits ballistic transport of electrons, meaning the presented electrons can travel long distances without scattering. Graphene (2) also ascribes remarkably high thermal conductivity, and this allows phonons to travel rapidly through graphene (2); this is due to the hexagonal lattice arrangement of graphene's (2) carbon atoms and the correlating strong carbon-carbon bonds of these atoms. Thermal conductivity becomes salient particularly regarding the extreme cryogenic environment customary with quantum computers. An absolute assembled prototype of my invention produces an explicit structure comprising two separate identical mercury telluride (1) layers bilaterally enclosing a central graphene (2) layer, in which all exterior surfaces present on this graphene (2) and mercury telluride (1) structure is entirely encased with an external layer of gold (4), consequentially a finished fabrication of said structure conduces a beneficial environment favoring electrical currents. These previously mentioned materials postulate cooperative interactions between them in direct correlation with the precise adjoining arrangement formed by an absolute assembly of my invention, and this specific information essentially derives an acknowledgment that warrants applying implicit consideration concentrating upon the capacity each of these said materials potentially capable of reinforcing the individual electrically conductivity attributed by each the other corresponding materials presented in my invention: incorporating their explicit arrangement, these said materials also bear capability to potentially amplify the individual electrical conductivity exhibited by each of the other corresponding materials included. Transferring and fundamentally integrating superfluid helium-4 (3) directly into the central graphene (2) layer that is interiorly established explicitly as the center of the tri-layer structure comprising my invention, whereas this said integration of superfluid helium-4 (3) incorporates accurately guiding its transfer contiguously into central graphene (2) layer, in which this said integration consisting of introducing a confined graphene (2) layer with superfluid helium-4 (3) is optimally obtainable through constructing my invention to intentionally accommodate the incorporation of microfluidic channels (6) composed of inconel. A complete ion trap embodiment prototype of my invention also obliges that it is independently designed incorporating the integration of one or more properly equipped hermetic sealing mechanisms (5) and this is concretely reliant upon the individual ion trap system employing my invention. The process of first designing, followed by then manufacturing, incorporating, installing, and finally utilizing the finished fabrication of the inconel microfluidic channels (6), is directly ensued by accurately guiding the transportation of superfluid helium-4 (3) contemporarily present within the cryogenic vacuum environment, essentially transferring this said superfluid helium-4 (3) directly into the central graphene (2) layer. This particular integration undoubtedly augments the electrical conductivity of this said central graphene (2) layer, in conjunction with simultaneously augmenting the electrical conductivity attributed by the entire system. Mentioning the comprehensive acknowledgment relating to graphene's (2) electron mobility invariably increasing at lower temperatures, stated in collaboration with the fact that extremely low temperatures are requisite for helium-4 to transition into its superfluid state. An expected key feature potentially demonstrated through equipping, employing, and utilizing my invention regards the phonons present within the graphene (2) layer, and this information derives an inclination relating to an attribute my invention is presumably capable of manifesting through this integration of superfluid helium-4 (3) by precisely guiding the transfer of this said superfluid helium-4 and transporting it directly into the central graphene (2) layer of my invention. Phonon coupling and, or phonon scattering can presumptively arise within the central graphene (2) layer of my invention, upon the integration of superfluid helium-4 (3) into this said central graphene (2) layer. Phonon coupling is the interactions between phonons and other particles, or quasiparticles, present within a material and concerning the proposed structure of my invention, coupling between the excitations in the superfluid helium-4 (3) and the phonons in the graphene (2) layer is predictable. Phonon scattering refers to the process by which phonons are deflected or disrupted from their original paths; in which a reduction in phonon activity is also favorably predictable given the components' specific arrangement involved in a finished composition of this superfluid helium-4 (3) integrated graphene (2) layer. Phonon coupling and phonon activity both are directly correlated to a material's electron mobility. Electron tunneling is also worth mentioning since it could potentially manifest in an integration of superfluid helium-4 (3) introduced into a confined layer of graphene (2): while electron tunneling refers to the quantum mechanical phenomenon where electrons can pass through energy barriers that would be impossible to overcome in classical physics. Considering the parameters and the potential environment provided with a complete fabrication of my invention, electrical currents are expected to be exemplarily, and precisely manipulated. My invention positively transpires unsurpassable electron mobility because my invention furnishes the most favorable environment for electrons to travel throughout its interior, as well as providing electrons an exceptional ability to travel along the exterior surface of my invention. This said environment potentially demonstrated by my invention, is ideal for the trapping and manipulation of ions. My invention would produce exceptional electrical conductivity illustrated by stable surface states collectively bearing identical conditions along the entire exterior of my invention. The interior of my invention would also provide an environment beneficial for electrical conductivity, allowing for robust ion manipulation considering an ion trap quantum computer equipping my invention. Cogitated on the favorable cooperative interactions between the materials included in an approximate assemblage of a prototype of my invention: in which my invention infers to attribute a stable environment to precisely transmit electrical signals throughout its interior, while simultaneously supporting the secure externally established surface states of substantial importance. An absolute fabrication of my invention enabled as an ion trap embodiment catered towards it's foremost practical application to be incorporated into an ion trap quantum computer, in which this particular ion trap embodiment of my invention presumably capable of demonstrating notably meritorious results considering the following: gold (4) is the best known conductor of electricity, and a layer of gold (4) is assembled as an exterior layer encasing my invention, including this layer of gold (4) is in direct contact with a both separate layers of mercury telluride (1), in which mercury telluride (1) retains the ability to exceptionally maintain sustainable surface states, as well as mercury telluride (2) being accredited with the ability to conduct electricity remarkably well. Mercury telluride (1) also contains an insulating bulk that simultaneously provides it with the ability to replicate, or efficiently manipulate, an electrical signal throughout this insulating interior, transmitting the signal to the opposite outermost corresponding layer located on the other side of this interior insulating bulk that forms a single mercury telluride (1) layer. Continuing that this inward facing, exterior surface of the mercury telluride (1) layer is in nonvariable contact with, and fundamentally connected to the internal central layer of graphene (2) within my invention. Considering graphene (2) is extremely durable and strong, graphene (2) also effectively conducts heat, as well as graphene (2) attributes an exceptional ability to conduct electricity, in addition to graphene's (2) atomic structure also allowing for the phenomena known as the ballistic transport of electrons. Concerning this central layer of graphene (2) internally constructed within my invention consequently bears an intended integration of superfluid helium-4 (3) introduced into this said central graphene (2) layer, whereas the superfluid helium-4 (3) holds potential to productively amplify the electrical and thermal conductive qualities of this central graphene (2) layer, along with this integration of superfluid helium-4's (3) into the central graphene (2) layer also simultaneously contributing to the effective reinforcement, structural integrity, stability, and strength of this central graphene (2) layer. This allows for the precise direction of an initial governing electrical signal introduced to one of the exterior surfaces of the encasing layer of gold (4), and this particular electrical signal is administrable through accurate guidance from this said external surface layer of gold (4), through one of the adjacent layers of mercury telluride (1), and this electrical signal is then able to be carefully distributed throughout the superfluid helium-4 (3) integrated central graphene (2) layer whereas this initial governing electrical signal can efficiently be administered, manipulated, and, or replicated onto the adjacent innermost surface of the second bilaterally placed mercury telluride (1) layer. This specific process is adjustable and replicable throughout the second said bilateral layer of mercury telluride (1) and given that this second layer of mercury telluride (1) is also entirely encased by the outermost layer of gold (4). With all of that being stated, a designated initially dispatched governing electrical signal is capable of being meticulously and uniformly transmitted from one of the eternal surfaces of my invention; in which this said electrical signal bears the ability to then be precisely guided throughout the interior of my invention onto the opposing exterior surface of my invention, giving this initial electrical signal an illustrious ability to induce, trap, manipulate, replicate, and create ions, ions capable of displaying favorable entanglement properties.

Concluding this disclosure containing updated information essentially addresses the amount of experimentation required to manufacture a prototype of my proposed invention, as well validating the fact that undue experimentation is not necessitated. An undue experimentation assumption is absolutely relinquished upon analyzing the data introduced by disclosure of this application. Coupling the acute analysis of this said data with simulations of the results produced from the data examination factors, effectively enables someone skilled in the art of my invention to make and use my invention. Predicting the outcome of my invention is achievable through employing various simulation methods, or through employing a combination of these said methods, included herein: computational modeling software, finite element analysis, particle-in-cell simulation, quantum mechanical simulation, high-performance computing, and/or experimental data. Predictions derived from these said methods, or a combination of these methods, promotes the notion that any undue experimentation is negated, since these said simulations are capable of effectively predicting the resultants of my invention under varying conditions, prior to the actual physical conduction of this said experimentation. Computational Modeling Software can simulate the behavior of ions in an electric field by using software such as COMSOL, ANSYS, SIMION, or Multiphysics. Finite Element Analysis software aids in analyzing the structural integrity and electric field distribution within anion trap. The Particle-in-Cell Simulation method simulates the ion of ions in an ion trap by tracking individual particles in an electric field. Quantum Mechanical Simulation provide insights into the behavior of ions at the atomic level and involves using Gaussian, or Quantum ESPRESSO software. High-Performance Computing I needed to efficiently run simulations. All these methods are employable prior to conducting any physical experimentation.

1: A tri-layer laminate comprising: a graphene (2) layer integrated with superfluid helium-4, wherein said graphene (2) layer comprises multiple graphene (2) sheets; said graphene (2) layer integrated with superfluid helium-4 encased between two separate layers of mercury telluride (1); a layer of gold (4) encasing said two separate layers of mercury telluride (1); a hermetic seal (5) incorporated within the tri-layer laminate to isolate the superfluid helium-4 (3) from external environments; and microfluidic channels (6) configured to allow the transfer of superfluid helium-4 (3) into said graphene (2) layer.

2: The tri-layer laminate of claim 1, wherein said graphene (2) layer comprises 3 to 10 graphene (2) layers.

3: The tri-layer laminate of claim 1, wherein said multiple graphene (2) layers have a combined thickness between 1 and 10 nanometers.

4: The tri-layer laminate of claim 1, wherein said mercury telluride (1) layers are each independently of a thickness between 10 and 100 nanometers.

5: The tri-layer laminate of claim 1, wherein said layer of gold (4) has a thickness between 10 and 50 nanometers.

6: The tri-layer laminate of claim 1, wherein the tri-layer laminate is configured to be used as an ion trap in an ion trap quantum computer.

7: The tri-layer laminate of claim 1, wherein the microfluidic channels (6) are composed of Inconel.

8: The tri-layer laminate of claim 6, wherein the hermetic seal (5) is integrated within the tri-layer laminate to isolate the superfluid helium-4 (3) from external environments.

9: The tri-layer laminate of claim 8, wherein said hermetic seal (5) comprises a material selected from the group consisting of gold (4), titanium, and glass.

10: The tri-layer laminate of claim 8, wherein the hermetic seal (5) is configured to maintain vacuum conditions within the tri-layer laminate.
